(19) United States
(12) Patent Application Publication
(10) Pub. No.: US 2020/0157683 A1
(43) Pub. Date: May 21, 2020

(54) FILM-FORMING PROCESSING APPARATUS, FILM-FORMING METHOD, AND STORAGE MEDIUM

(71) Applicant: TOKYO ELECTRON LIMITED, Tokyo (JP)

(72) Inventors: Hitoshi KATO, Oshu-shi (JP); Kazuhide HASEBE, Nirasaki City (JP)

(73) Assignee: TOKYO ELECTRON LIMITED, Tokyo (JP)

(21) Appl. No.: 16/750,390

(22) Filed: Jan. 23, 2020

Related U.S. Application Data
(62) Division of application No. 15/200,258, filed on Jul. 1, 2016.

(30) Foreign Application Priority Data
Jul. 6, 2015 (JP) 2015-135370

(51) Int. Cl. C23C 16/46; C23C 16/455

(52) U.S. Cl. CPC C23C 16/46; C23C 16/45551

(57) ABSTRACT

A film-forming processing apparatus includes a first heater heating an entire heat treatment region of a substrate, a second heater heating the substrate to have an in-plane temperature distribution having a concentric shape, a gas supplier supplying a process gas to a rotary table; and a control part outputting a control signal for executing a first step of setting a rotation position of the rotary table such that the substrate on the rotary table is placed in a position corresponding to the second heater and forming the in-plane temperature distribution having the concentric shape on the substrate by heating the substrate by the second heater, and a second step of performing a film forming process on the substrate by rotating the rotary table in a state where a heating energy received by the substrate from the second heater is smaller than that in the first step.

### CROSS-REFERENCE TO RELATED APPLICATION(S)

This application claims the benefit of Japanese Patent Application No. 2015-135370, filed on Jul. 6, 2015, in the Japan Patent Office, the disclosure of which is incorporated herein in its entirety by reference.

### TECHNICAL FIELD

The present disclosure relates to a technical field of performing a film forming process by supplying a process gas to a substrate, while the substrate is revolved.

### BACKGROUND

In a process of manufacturing a semiconductor device, for example, atomic layer deposition (ALD) is performed to form various films for forming an etching mask or the like on a semiconductor wafer (hereinafter, referred to as “wafer”) as a substrate. In order to increase the productivity of a semiconductor device, ALD may be performed by an apparatus in which a rotary table on which a plurality of wafers are mounted is rotated to allow the wafers to revolve, so that the wafers repeatedly pass through a process gas supply region (process region) disposed along a diameter direction of the rotary table. Further, in order to form each of the films, chemical vapor deposition (CVD) may be performed. The film formation through CVD may also be considered to be performed by allowing the wafers to revolve, like ALD.

However, in an etching device that etches the wafers after film formation, etching may be performed such that etching rates of respective portions of the wafer in a diameter direction are different. Accordingly, film formation may be required to be performed to have a concentric circular shape with respect to a film thickness distribution of the wafer. More specifically, the film thickness distribution having a concentric circular shape refers to a film thickness distribution in which film thicknesses are equal or substantially equal in each position along a circumferential direction of a wafer at an equal distance from the center of the wafer and different in each position along a diameter direction of the wafer.

However, in a film forming apparatus in which the wafer is revolved, since the process gas is supplied in a diameter direction of the rotary table as mentioned above, a distribution of film thicknesses formed on the wafer tends to be a film thickness distribution in which the film thicknesses are changed from the center side of the rotary table toward the peripheral side thereof, making it difficult to form a film thickness distribution having a concentric circular shape. Conventionally, a film forming apparatus for forming the film thickness distribution having a concentric circular shape by performing CVD in a state where a predetermined temperature distribution is formed in a plane of the wafer is presented, but in this film forming apparatus, the wafer does not revolve during a film forming process. Thus, the related art cannot solve the above problem.

### SUMMARY

Some embodiments of the present disclosure provide a technique capable of performing film formation on a substrate such that a film thickness distribution having a concentric circular shape is formed, in an apparatus for performing a film forming process by revolving the substrate by a rotary table.

According to one embodiment of the present disclosure, a film-forming processing apparatus for performing a film formation by supplying a process gas to a substrate which is mounted on one surface side of a rotary table installed in a vacuum vessel, the substrate being revolved by a rotation of the rotary table, including: a first heating part configured to heat an entire heat treatment region of the substrate in the vacuum vessel; a second heating part installed to face the rotary table, corresponding to the substrate mounted on the rotary table and configured to heat the substrate to have an in-plane temperature distribution having a concentric shape; a process gas supply part configured to supply the process gas to the one surface side of the rotary table; and a control part configured to output a control signal for executing a first step of setting a rotation position of the rotary table such that the substrate on the rotary table is placed in a position corresponding to the second heating part and forming the in-plane temperature distribution having the concentric shape on the substrate by heating the substrate by the second heating part, and a second step of performing a film forming process on the substrate by rotating the rotary table in a state where a heating energy received by the substrate from the second heating part is smaller than that in the first step.

According to one embodiment of the present disclosure, a method of forming a film by supplying a process gas to a substrate which is mounted on one surface side of a rotary table installed in a vacuum vessel, the substrate being revolved by a rotation of the rotary table, including: using a first heating part and a second heating part, the second heating part being installed to face the rotary table, corresponding to the substrate mounted on the rotary table; heating an entire heat treatment region of the substrate in the vacuum vessel by the first heating part; setting a rotation position of the rotary table such that the substrate on the rotary table is placed in a position corresponding to the second heating part and forming an in-plane temperature distribution having a concentric shape on the substrate by heating the substrate by the second heating part; and performing a film forming process by supplying a process gas to the substrate by rotating the rotary table in a state where a heating energy received by the substrate from the second heating part is smaller than that in the first step.

According to one embodiment of the present disclosure, a non-transitory computer-readable recording medium storing a program for use in a film-forming processing apparatus for performing a film formation by supplying a process gas to a substrate which is mounted on one surface side of a rotary table installed in a vacuum vessel, the substrate being revolved by a rotation of the rotary table, wherein the program has groups of steps organized to execute the method of forming a film described above.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal side view of a film forming apparatus of the present disclosure.

FIG. 2 is a schematic cross-perspective view of the film forming apparatus.

FIG. 3 is a cross-sectional plane view of the film forming apparatus.

FIG. 4 is a longitudinal side view of a rotary table and a process vessel installed in the film forming apparatus along a circumferential direction of a ceiling.

FIG. 5 is a cross-sectional plane view of the rotary table of the film forming apparatus when viewed from a downward side.

FIG. 6 is a schematic longitudinal side view illustrating the operation of the film forming apparatus.

FIG. 7 is a schematic longitudinal side view illustrating the operation of the film forming apparatus.

FIG. 8 is a schematic longitudinal side view illustrating the operation of the film forming apparatus.

FIG. 9 is a schematic view illustrating the state of the wafer subjected to the film forming process.

FIG. 10 is a schematic view illustrating the state of the wafer subjected to the film forming process.

FIG. 11 is a schematic view illustrating the state of the wafer subjected to the film forming process.

FIG. 12 is a schematic view illustrating the state of the wafer subjected to the film forming process.

FIG. 13 is a schematic view illustrating the state of the wafer subjected to the film forming process.

FIG. 14 is a schematic cross-sectional plane view illustrating the flow of a gas provided in the film forming apparatus.

FIG. 15 is a schematic view illustrating the state of the wafer subjected to the film forming process.

FIG. 16 is a perspective view illustrating another configuration example of the rotary table.

FIG. 17 is a graph illustrating the result of an evaluation test.

FIG. 18 is a graph illustrating the result of an evaluation test.

FIG. 19 is a graph illustrating the result of an evaluation test.

FIG. 20 is a graph illustrating the result of an evaluation test.

FIG. 21 is a graph illustrating the result of an evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

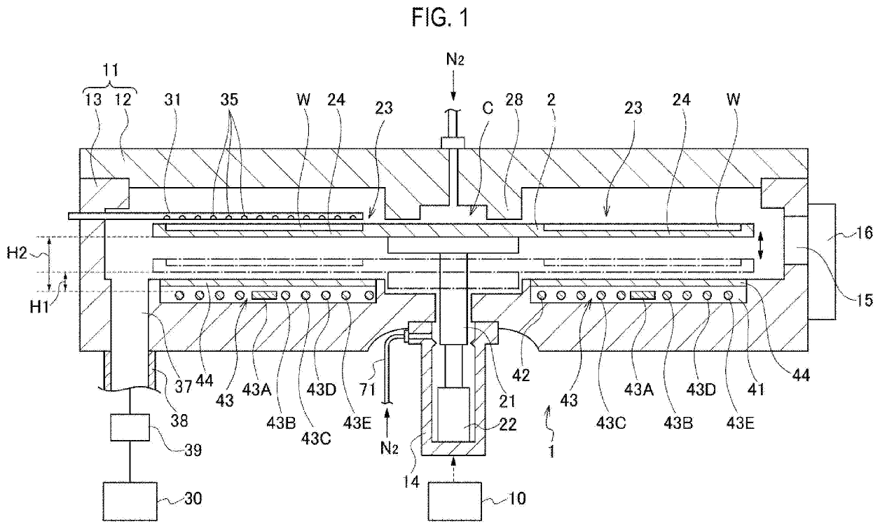

A film-forming processing apparatus 1 for performing ALD on a wafer W as a substrate to form a titanium oxide (TiO₂) film according to an embodiment of the present disclosure will be described with reference to FIGS. 1 to 3. In order to form a film thickness distribution having a concentric circular shape in a plane of the wafer W that is a circular substrate, the film-forming processing apparatus 1 performs a film forming process by forming a temperature distribution having a concentric circular shape in the plane of the wafer W and supplying a process gas in a state where the temperature distribution is formed in this manner. More specifically, the temperature distribution having a concentric circular shape refers to a temperature distribution in which positions along a circumferential direction of the wafer W, which are equidistant from the center of the wafer W, have the same or substantially same temperature, while positions along a diameter direction of the wafer W have different temperatures.

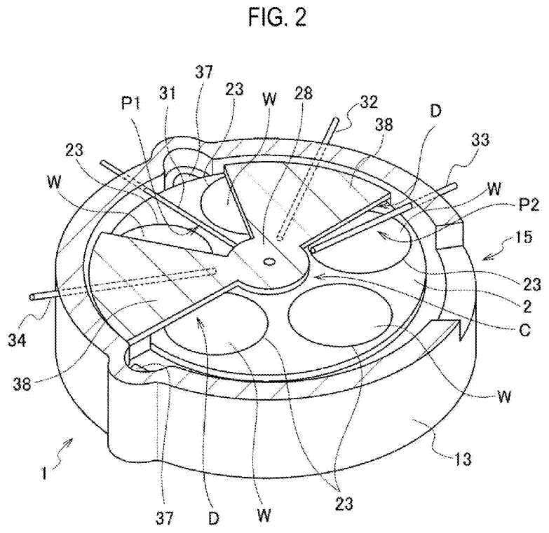

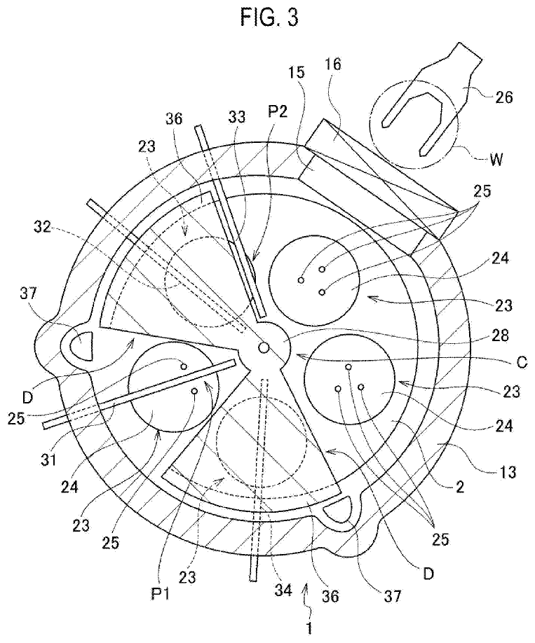

FIG. 1 is a longitudinal side view of the film-forming processing apparatus 1, FIG. 2 is a schematic perspective view illustrating the inside of the film-forming processing apparatus 1, and FIG. 3 is a cross-sectional plane view of the film-forming processing apparatus 1. The film-forming processing apparatus 1 includes a flat vacuum vessel (process vessel) 11 having a substantially circular shape and a horizontal rotary table 2 having a disk shape installed in the vacuum vessel 11. The vacuum vessel 11 is configured by a ceiling plate 12 and a vessel body 13 that forms the sidewall and the bottom of the vacuum vessel 11. In FIG. 1, reference numeral 14 denotes a cover covering a lower central portion of the vessel body 13. In FIG. 1, reference numeral 71 denotes a gas supply pipe which supplies a nitrogen (N₂) gas as a purge gas into the cover 14 to purge a lower surface side of the rotary table 2 during the film forming process.

An upper end of a vertical support shaft 21 is connected to a central portion of the lower surface side of the rotary table 2, and a lower end of the support shaft 21 is connected to a driving mechanism 22, which is a making-close or making-far mechanism, installed in the cover 14. The rotary table 2 is configured to ascend and descend between an ascending position indicated by the solid line in FIG. 1 and a descending position indicated by the two-dot chain line in FIG. 1, and rotate in a circumferential direction of the rotary table 2, by the driving mechanism 22. Five circular concave portions 23 are formed to be spaced apart from one another in a rotation direction of the rotary table 2 in a surface side (one surface side) of the rotary table 2, the wafer W is horizontally mounted on a bottom surface 24 of the concave portion 23, and the mounted wafer W is rotated according to the rotation of the rotary table 2. A sidewall of the concave portion 23 regulates a position of the wafer W mounted on the bottom surface 24. In order to form a temperature distribution having a concentric circular shape by a heater 43 described later on the wafer W mounted on the bottom surface 24, the rotary table 2 is preferably formed of a material having a relatively high thermal conductivity, for example, quartz, but it may also be formed of a metal such as, for example, aluminum.

Holes denoted by reference numeral 25 in FIG. 3 form a hoist way for three lift pins 27 (not shown in FIGS. 1 to 3) for transferring the wafer W between a wafer transfer mechanism 26 for performing loading and unloading of the wafer W with respect to the film-forming processing apparatus 1 and the concave portions 23. Three holes are formed on each of the bottom surfaces 24 by passing through the rotary table 2 in a vertical direction. Further, a transfer port 15 of the wafer W is open on the sidewall of the vacuum vessel 11, and is configured to be opened and closed by a gate valve 16. Through the transfer port 15, the wafer transfer mechanism 26 is moved between the exterior of the vacuum vessel 11 and the interior of the vacuum vessel 11 to transfer the wafer W to or from the concave portion 23 at a position facing the transfer port 15 through the lift pins 27.

A bar-shaped raw material gas nozzle 31, a separation gas nozzle 32, an oxidizing gas nozzle 33, and a separation gas nozzle 34 extending from an outer periphery of the rotary table 2 toward the center thereof are sequentially disposed in an upper side of the rotary table 2 at intervals in a circumferential direction of the rotary table 2. These gas nozzles 31 to 34 have a plurality of openings 35 in a length direction therebelow and supply gases along a diameter of the rotary table 2. The raw material gas nozzle 31 as a process gas supply part discharges a titanium (Ti)-containing gas such as, for example, a titanium methyl pentane-dionato-bis-tetra-methyl-heptane-dionato (Ti(MPD)(THD)) gas, which is a raw material gas, as a process gas for performing film formation. The oxidizing gas nozzle 33 discharges, for example, an ozone (O₃) gas, as an oxide gas for oxidizing a Ti-containing gas. The separation gas nozzles 32 and 34 discharge, for example, a nitrogen (N₂) gas.

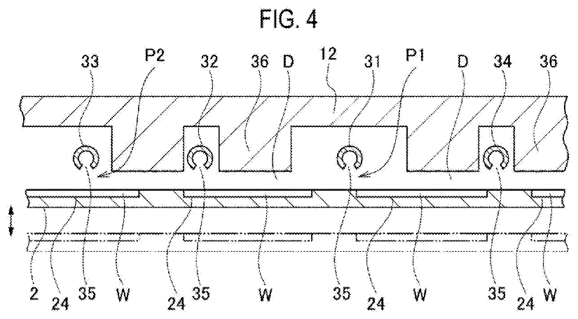

FIG. 4 illustrates a longitudinal side surface along the periphery of the rotary table 2 and the ceiling plate 12 of the vacuum vessel 11. Referring to FIG. 4, the ceiling plate 12 downwardly protrudes and has two protrusion portions 36 having a fan shape formed in a circumferential direction of the rotary table 2, and the protrusion portions 36 are formed to be spaced apart from each other in the circumferential direction. The separation gas nozzles 32 and 34 are installed to be deeply embedded in the protrusion portions 36 to divide the protrusion portions 36 in the circumferential direction. The raw material gas nozzle 31 and the oxidizing gas nozzle 33 are installed to be spaced apart from each of the protrusion portions 36.

In FIG. 4, the rotary tables 2 in an ascending position and a descending position are indicated by the solid line and the two-dot chain line, respectively. When the rotary table 2 is placed in the ascending position, the rotary table 2 is rotated and a gas is supplied from each of the gas nozzles 31 to 34. A gas supply region below the raw material gas nozzle 31 will be referred to as a first process region P1 and a gas supply region below the oxidizing gas nozzle 33 will be referred to as a second process region P2. Further, the protrusion portions 36 are adjacent to the rotary table 2 placed in the ascending position. As the protrusion portions 36 are adjacent in this manner and an N₂ gas (separation gas) is supplied from the separation gas nozzles 32 and 34, gaps between the rotary table 2 and the protrusion portions 36 are configured as separation regions D for separating the atmospheres of the process regions P1 and P2.

On the bottom surface of the vacuum vessel 11, two exhaust ports 37 are opened at an outer side of the rotary table 2 in a diameter direction. As illustrated in FIG. 1, one end of an exhaust pipe 38 is connected to each of the exhaust ports 37. The other end of each of the exhaust pipes 38 joins to be connected to an exhaust mechanism 30 configured by a vacuum pump through an exhaust amount adjusting part 39 including a valve. An exhaust amount from each exhaust port 37 is adjusted by the exhaust amount adjusting part 39, thereby adjusting an internal pressure of the vacuum vessel 11.

A space in a region C of the central portion of the rotary table 2 is configured such that an N₂ gas is supplied thereto. The N₂ gas flows as a purge gas to an outer side of the rotary table 2 in a diameter direction through a flow channel below a ring-shaped protrusion portion 28 protruding to have a ring shape from a lower portion of the central portion of the ceiling plate 12. The lower surface of the ring-shaped protrusion portion 28 is configured to be connected to a lower surface of the protrusion portion 36 forming the separation region D.

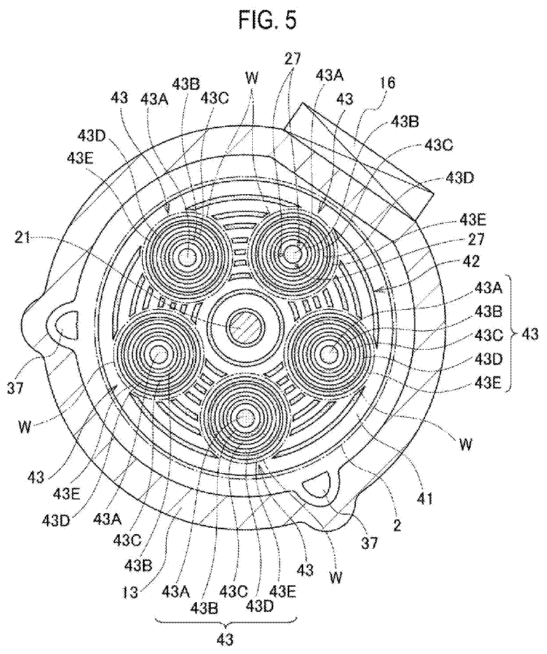

As illustrated in FIG. 1, a concave portion having a circular ring shape forming a heater receiving space 41 in a rotation direction of the rotary table 2 is formed below the vessel body 13. FIG. 5 is a plane view illustrating the heater receiving space 41. In the heater receiving space 41, a heater 42, which is a first heating part, for heating the entire inside of the vacuum vessel 11 as a heat treatment region, and a heater 43, which is a second heating part, for heating the inside of the vacuum vessel 11 and forming a temperature distribution having a concentric circular shape on the wafer W are installed to face each other on the rotary table 2. In order to facilitate determining where the heaters are located in the drawing, a plurality of dots are attached to the heaters 42 and 43 to indicate the heaters 42 and 43 in FIG. 5. The heaters 42 and 43 are disposed to be spaced apart from each other in a traverse direction, without overlapping each other.

The heater 43 heats each wafer W mounted on the rotary table 2 in a state where the rotary table 2 is placed in the descending position and is stopped from rotation, and five heaters are installed to form a temperature distribution having a concentric circular shape on the plane of each wafer W. One heater 43 includes heater elements 43A to 43E. The heater element 43A has, for example, a disk shape. The heater elements 43B to 43E have circular ring shapes having different diameters and are disposed to have a circular shape concentric to the heater element 43A. Diameters of the rings satisfy the following relationship: 43E>43D>43C>43B. The heater elements 43A to 43E are configured to be controlled in output individually, and in this example, the heater elements 43B and 43C are controlled to have the same temperature and the heater elements 43D and 43E are controlled to have the same temperature.

In FIG. 5, a position relation between the wafer W and the heater elements 43A to 43E when heating is performed to form the temperature distribution is illustrated. When a region having a ring shape between the central portion and the peripheral portion of the wafer W is referred to as a middle portion and when the temperature distribution is formed on the wafer W in this manner, the heater elements 43A, 43B and 43C, and 43D and 43E are placed below the central portion, the middle portion, and the peripheral portion, respectively, and have different temperatures. Accordingly, the central portion, the middle portion, and the peripheral portion of the wafer W are heated to have different temperatures, forming a temperature distribution having a concentric circular shape on the wafer W. A distance, indicated by H1 in FIG. 1, between the lower surface of the rotary table 2 and each of the heater elements 43A to 43E in the descending position when the temperature distribution is formed on the wafer W in this manner is, for example, 3 mm to 4 mm. Also, a distance, indicated by H2 in FIG. 1, between the lower surface of the rotary table 2 and the heater elements 43A to 43E is, for example, 10 mm to 15 mm.

Referring back to FIG. 5, the heater 42 will be described. The heater 42 includes a plurality of heater elements having a curved shape disposed along a concentric circle having a center at a rotation axis of the rotary table 2 on an outer side of the region in which the heater element 43E is installed. In the heater 42, for example, a heater element (referred to as the outermost heater element) disposed on the outermost side of the heater receiving space 41, among the heater elements forming the heater 42 is placed below the peripheral portion of the rotary table 2, and a heater element (referred to as the innermost heater element) disposed on the innermost side of the heater receiving space 41 is placed on a more inner side than a position of the heater element 43E closest to the rotation center of the rotary table 2, in order to heat the entire inside of the vacuum vessel 11. In addition, other heater elements forming the heater 42 are plurally disposed between the innermost heater element and the outermost heater element, when viewing the heater receiving space 41 in a diameter direction. Also, the above-described lift pins 27 are disposed so as not to interfere with the heaters 42 and 43 during the ascending and descending operation.

Further, a plate 44 (see FIG. 1) is installed to cover the concave portion forming the heater receiving space 41 from above, and the heater receiving space 41 is partitioned by the plate 44 from an atmosphere in which a raw material gas and an oxide gas are supplied. Although not shown, a purge gas is supplied to the heater receiving space 41 while the wafer W is processed, and a gas supply pipe for preventing the entry of a process gas to the receiving space 41 is connected to a lower portion of the vessel body 13.

In the film-forming processing apparatus 1, a controller 10 configured as a computer for controlling the overall operation of the apparatus is installed. A program for executing a film forming process described later is stored in the controller 10. The program controls the operation of each part of the film-forming processing apparatus 1 by transmitting a control signal to each part. Specifically, each operation such as the supply or stop of each gas to each of the gas nozzles 31 to 34 and the region C of the central portion from a gas supply source (not shown), the ascending and descending of the rotary table 2 by the driving mechanism 22 and the controlling of a rotational speed of the rotary table 2, the adjustment of an exhaust amount from each of the vacuum exhaust ports 37 by the exhaust amount adjusting part 39, or the controlling of a temperature of each portion of the wafers W and the vacuum vessel 11 by supplying a power to the heaters 42 and 43 is controlled.

In the program, groups of steps are organized such that each process described later is executed by controlling these operations. Further, the program is installed in the control part 10 from a storage medium such as a hard disk, a compact disk, a magneto-optical disk, a memory card, or a flexible disk.

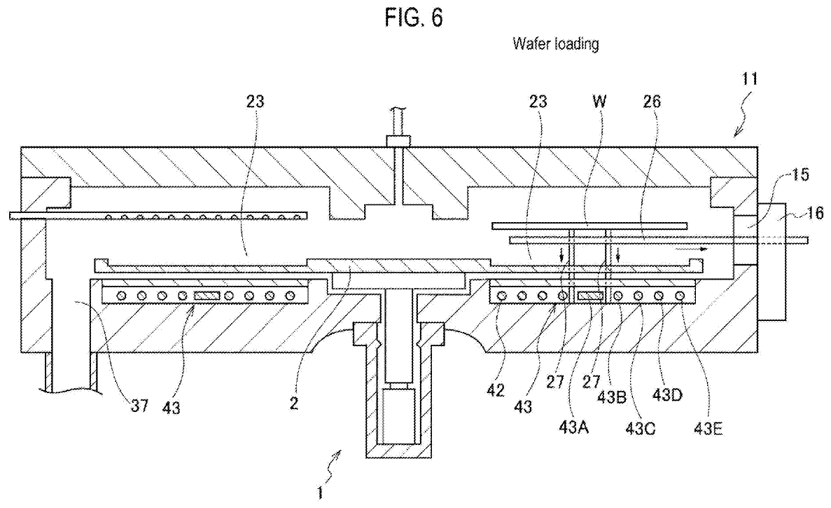

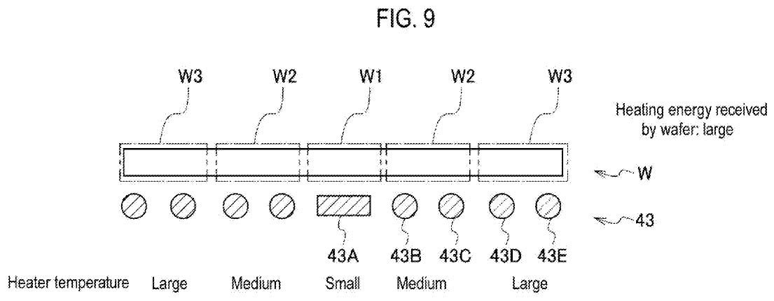

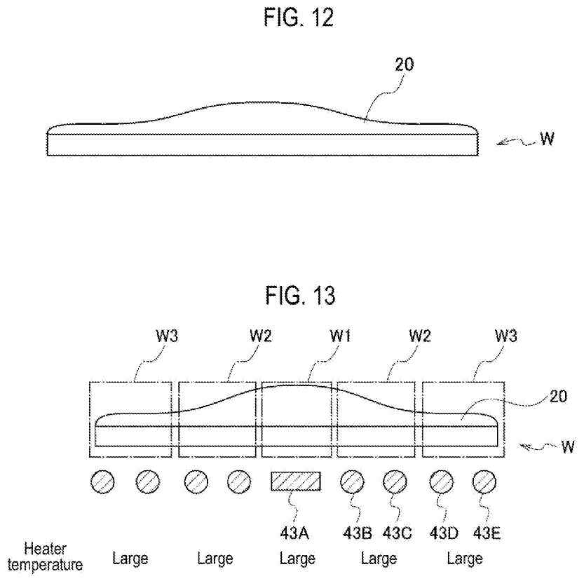

Next, an operation performed by the film-forming processing apparatus 1 will be described with reference to schematic longitudinal side views of FIGS. 6 to 8. Also, it will be described appropriately with reference to FIGS. 9 to 13 as views illustrating the state of the wafer W during the operation of the film-forming processing apparatus 1. In each of the drawings of FIGS. 9 to 13, excluding FIG. 12, a central portion, a middle portion, and a peripheral portion of the wafer W will be indicated by W1, W2, and W3, respectively, for the convenience of description. Also, in FIGS. 9 to 11 and 13, as schematically illustrating the temperatures of W1 to W3 or the temperatures of the heater elements by three stages, a distribution of temperatures in W1 to W3 or a distribution of temperatures in each of the heater elements 43A to 43E is illustrated by attaching the characters of small, medium, and large. In the film forming process described in FIGS. 6 to 13, the temperature of the heater 43 is controlled to have a film thickness distribution having a concentric circular shape in which a film thickness at the central side of the wafer W is greater than that of the peripheral side.

First, in a state where the rotary table 2 is placed in the descending position, the temperatures of the heater elements 43A to 43E are increased, and here, the temperatures are 43A<43B=43C<43D=43E. Also, the temperature of the heater 42 is increased, so that the entire inside of the vacuum vessel 11 is heated by the heaters 42 and 43. And then, in a state where the gate valve 16 is open, whenever the transfer mechanism 26 with the wafer W supported thereon enters into the vacuum vessel 11 through cooperation between the ascending and descending of the lift pins 27 and the intermittent rotation of the rotary table 2, the wafer W is transferred into the concave portion 23 (FIG. 6). Further, when the wafers W are received by five concave portions 23 and the transfer mechanism 26 is retracted from the vacuum vessel 11, the gate valve 16 is closed.

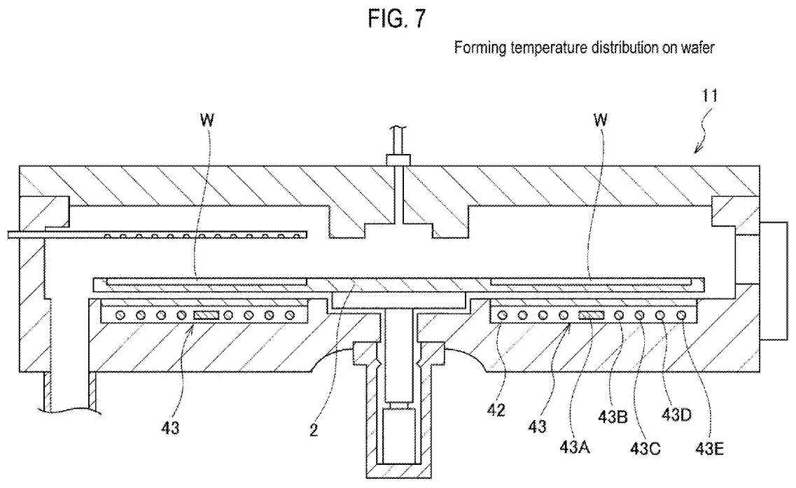

Thereafter, after the rotary table 2 is rotated such that the wafers W are placed above the heaters 43, the rotation of the rotary table 2 is stopped (FIG. 7). That is, the wafers W are stopped in the positions described above with reference to FIG. 5. By an exhaust from the exhaust port 37, the interior of the vacuum vessel 11 is adjusted to a vacuum atmosphere having a predetermined pressure. In parallel with the adjustment of pressure, the bottom surface 24 of the concave portion 23 of the rotary table 2 is heated by the heater 43, and accordingly, the wafer W is heated. Since the rotary table 2 is placed in the descending position and a distance between the rotary table 2 and the heater elements 43A to 43E is relatively short, the wafer W receives a relatively high heating energy from the heater elements 43A to 43E through the rotary table 2. Also, since the temperature distribution is formed between the heater elements 43A to 43E as described above, the temperature distribution having a concentric circular shape, in which the temperature of the peripheral side in the plane of the wafer W is higher than that of the center side, is formed (FIG. 9). For example, the wafer W is heated such that the central portion W1 has a temperature of 170 degrees C., the peripheral portion W3 has a temperature of 177 degrees C., and the middle portion W2 has a temperature higher than 170 degrees C. and lower than 177 degrees C.

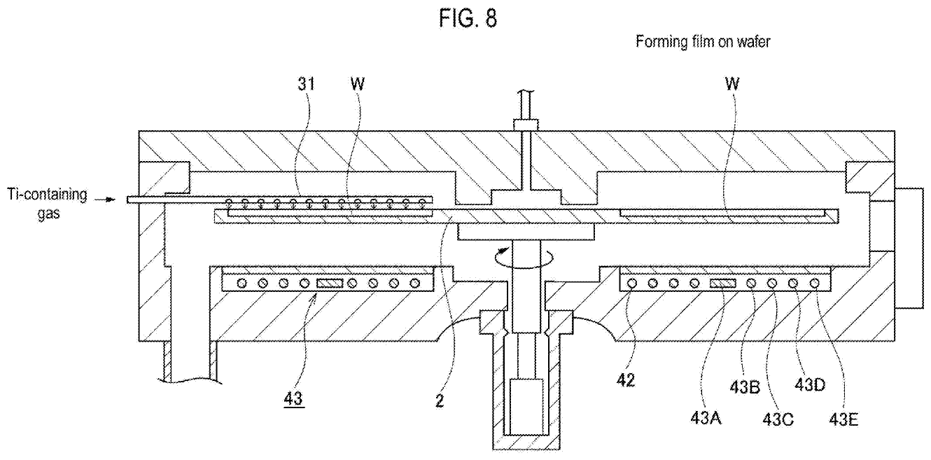

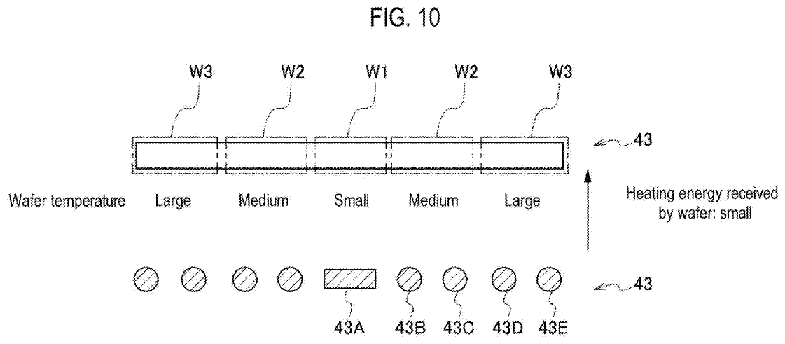

In a state where the temperature distribution having a concentric circular shape is formed in the wafer W in this manner, the rotary table 2 is moved to the ascending position, and thereafter, the rotary table 2 is rotated in a clockwise direction when viewed from the plane (FIG. 8). As the rotary table 2 ascends, the heating energy received by the wafer W from the heater elements 43A to 43E is reduced. For example, the temperatures of the heater elements 43A to 43E are kept to be the same as those when the rotary table 2 was in the descending position, even after the rotary table 2 is moved to the ascending position. As the distance between the rotary table 2 and the heater 43 is increased, it is difficult for the rotary table 2, further, for the wafer W, to be affected by the temperature of the heater elements 43A to 43E, and thus, the temperature distribution formed in the plane of the wafer W is maintained as described above (FIG. 10). In addition, a predetermined flow rate of an N₂ gas is supplied from the separation gas nozzles 32 and 34 and the region C of the central portion, and for example, a Ti-containing gas and an O₃ gas are supplied from the raw material gas nozzle 31 and the oxidizing gas nozzle 33, respectively.

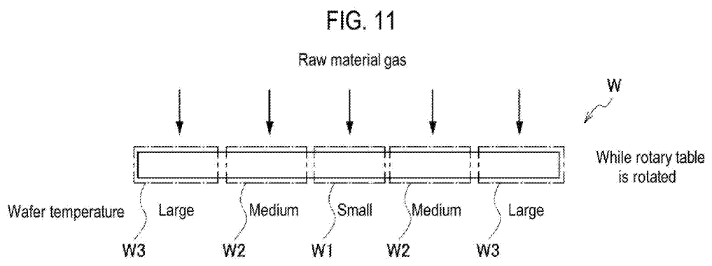

Further, the wafers W, on which the temperature distribution has been formed, alternately and repeatedly pass through the first process region P1 below the raw material gas nozzle 31 and the second process region P2 below the oxidizing gas nozzle 33 (FIG. 11). Accordingly, a cycle including adsorption of the Ti-containing gas to the wafer W and formation of a molecular layer of TiO₂ by oxidation of the adsorbed Ti-containing gas due to the O₃ gas is repeatedly performed to stack the molecular layers. While the cycle of ALD is performed, since the temperature distribution has been formed in the plane of the wafer W, an amount of adsorption of the Ti-containing gas is greater at the center side of the wafer W than the peripheral side. Further, the thickness of the molecular layer of TiO₂ formed during one cycle is large. As the molecular layers are stacked as described above, a TiO₂ film 20 having a concentric circular shape in which a film thickness at the center side is greater than that of the peripheral side is formed (FIG. 12).

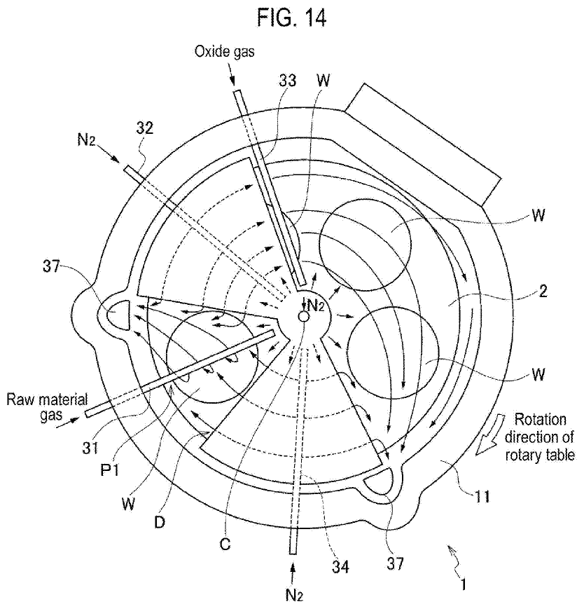

FIG. 14 illustrates the flows of respective gases in the vacuum vessel 11 when the cycle of the adsorption and oxidation of the Ti-containing gas is performed, by arrows. The N₂ gas as a separation gas supplied from the separation gas nozzles 32 and 34 to the separation region D spreads in the corresponding separation region in the circumferential direction to prevent the Ti-containing gas and the O₃ gas from being mixed on the rotary table 2. Also, the N₂ gas supplied to the region C of the central portion is supplied to an outer side of the rotary table 2 in the diameter direction to prevent the Ti-containing gas and the O3 gas) from being mixed in the region C of the central portion. Further, when the cycle is performed, the N₂ gas is also supplied to the heater receiving space 41 and the rear side of the rotary table 2 to purge the raw material gas and the oxidizing gas, as mentioned above.

While the cycle is performed, the temperature of each portion in the plane of the wafer W become gradually uniform due to movement of heat in the plane of the wafer W. Thus, for example, after the lapse of a predetermined time from a time at which the rotary table 2 moves to the ascending position, the supply of the Ti-containing gas and the O3 gas) is stopped, the rotary table 2 is moved to the descending position, and the rotation of the rotary table 2 is stopped so that each of the wafers W is placed above the heater 43. That is, the wafer W is again stopped in the position illustrated in FIGS. 5 and 7 and the temperature distribution having a concentric circular shape as described above is formed in the plane of the wafer W by the heater 43.

Thereafter, as illustrated in FIG. 8, the rotary table 2 is again moved to the ascending position and rotated in a clockwise direction. And then, the supply of each of the Ti-containing gas and the O₃ gas from the gas nozzles 31 and 33 is resumed, a molecular layer of TiO₂ is stacked on the wafer W, and thus, a film thickness of the TiO₂ film is increased in each portion in the plane of the wafer W. Also here, since the temperature distribution as mentioned above is formed on the wafer W, the thickness of the stacked molecular layer is greater in the center side of the wafer W than in the peripheral side of the wafer W, forming a film thickness distribution having a concentric circular shape. In this manner, a film thickness of the TiO₂ film 20 is increased in each portion in the plane of the wafer W.

After the lapse of a predetermined period of time from a time at which the rotary table 2 is again moved to the ascending position, when each portion in the plane of the wafer W has a desired film thickness, a supply amount of the N₂ gas to the separation gas nozzles 32 and 34 and the region C of the central portion is lowered to reach a predetermined flow rate, and the supply of a process gas from the gas nozzles 31 and 33 is stopped. The rotary table 2 is moved to the descending position, and the temperature of each of the heater elements 43A to 43E becomes a temperature of the heater elements 43D and 43E which had the highest temperature among the heater elements 43A to 43E when the temperature distribution was formed on the wafer W. And then, the rotary table 2 is stopped after the rotary table 2 is rotated such that each of the wafers W is placed above each of the heaters 43. That is, the wafers W are stopped in the positions of FIGS. 5 and 7 in which the above-described temperature distribution is formed.

Since the temperature of the heater 43 is adjusted as mentioned above, the entire plane of the wafer W has the highest temperature in the plane of the wafer W at the time when the temperature distribution was formed. When the temperature distribution is formed as described above, since the peripheral portion W3, among portions W1 to W3, has 177 degrees C., which is the highest temperature, and thus, here, the entirety of the wafers W is heated to 177 degrees C. (FIG. 13). In this manner, even in a case where there exists a difference in film quality of the TiO₂ film among the central portion W1, the middle portion W2, and the peripheral portion W3, due to the film formation by forming a temperature distribution, the difference is alleviated or resolved since the entire plane of the wafer W is heated. And then, after the lapse of a predetermined period of time from a time at which the rotation of the rotary table 2 is stopped, the gate valve 16 is opened and each of the wafers W is sequentially transferred to the transfer mechanism 26 which has entered into the vacuum vessel 11 according to cooperation between the ascending and descending of the lift pins 27 and the intermittent rotation of the rotary table 2 and is carried out from the vacuum vessel 11. In addition, when heating is performed to alleviate a difference in film quality among W1 to W3, the temperature of each of the heater elements 43A to 43E may be controlled such that the entire plane of the wafer W has a temperature higher than 177 degrees C., which is the highest temperature, in the plane of the wafer W at the time of the formation of the temperature distribution.

According to the film-forming processing apparatus 1, in performing the film forming process by supplying a raw material gas and an oxidizing gas to the wafer W while revolving the wafer W by rotating the rotary table 2, a step of heating the wafer W by the heater 43 is performed, such that an in-plane temperature distribution having a concentric circular shape is formed on the wafer W on the rotary table 2 in the descending position by the heater 43 before the raw material gas and the oxidizing gas are supplied. Thereafter, in a state where the rotary table 2 is moved to the ascending position and thus a heating energy applied to the wafer W is reduced, a step of revolving the wafer W and supplying the raw material gas and the oxidizing gas to the wafer W are performed to form a film. Accordingly, the film formation may be performed on the wafer W such that a film thickness distribution having a concentric circular shape is formed.

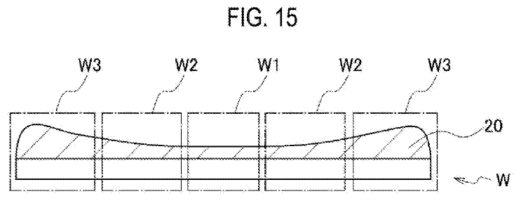

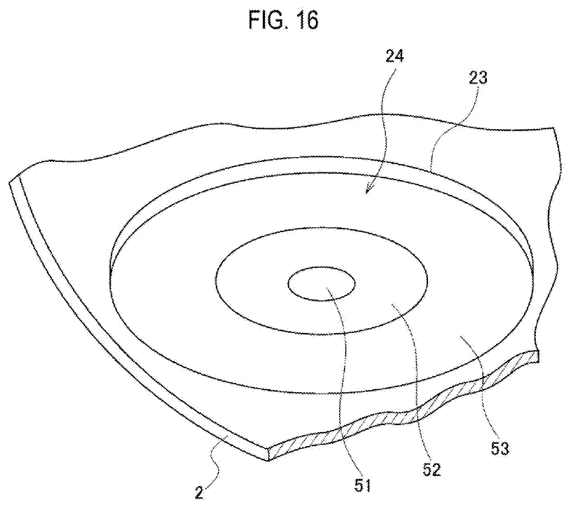

In the above, the example in which the TiO₂ film 20 is formed such that a film thickness distribution having a concentric circular shape in which a film thickness of the central portion of the wafer W is smaller than that of the peripheral portion of the wafer W is formed is illustrated. However, as illustrated in FIG. 15, the TiO₂ film 20 may be formed such that a film thickness distribution having a concentric circular shape in which a film thickness of the peripheral side of the wafer W is smaller than that of the center side thereof is formed. In this case, in forming the temperature distribution having a concentric circular shape in the plane of the wafer W in the film forming process, a temperature distribution is formed on the wafer W such that a temperature is lowered from the center of the wafer W toward the periphery thereof, instead of forming a temperature distribution on the wafer W such that a temperature is increased from the center of the wafer W toward the periphery thereof. Specifically, for example, the temperatures of the heater elements 43A to 43E are controlled to be 43A>43B=43C>43D=43E. Accordingly, in an example, the temperature of the central portion W1 of the wafer W is 170 degrees C., the temperature of the peripheral portion W3 is 163 degrees C., and the temperature of the middle portion W2 is smaller than 170 degrees C. and higher than 163 degrees C.

In the film forming process described above, a process of forming a temperature distribution having a concentric circular shape on the wafer W by the heater 43, and a process of forming a TiO₂ film using each gas by rotating the rotary table 2 in a state where energy received by the wafer W from the heater 43 is made smaller than that at the time of forming a temperature distribution, are repeatedly performed twice. However, the processes may also be repeatedly performed three or more times. Also, if the temperature distribution of the wafer W can be maintained for a sufficient period of time to obtain a desired film thickness, the process of forming the temperature distribution and the process of forming the TiO₂ film may not be repeatedly performed a plurality of times but may be performed only once.

However, the height of the rotary table 2 may be configured to be fixed in the vacuum vessel 11, in order to reduce a heating energy received by the wafer W from the heater 43 for the purpose of maintaining the temperature distribution-formed state after the temperature distribution having a concentric circular shape is formed on the wafer W. In this case, for example, the apparatus is configured such that a distance between the heater 43 and the wafer W is changed by changing the height of the heater 43 by the elevation mechanism.

Also, the present disclosure is not limited to the configuration in which the distance between the rotary table 2 and the heater 43 is changed in order to reduce the heating energy received by the wafer W from the heater 43 after the temperature distribution having the concentric circular shape is formed on the wafer W. For example, after the temperature distribution is formed on the wafer W, the heating energy supplied to the wafer W may be lowered by lowering the temperature of each of the heater elements 43A to 43E of the heater 43 to a temperature lower than that of each of the heater elements 43A to 43E at the time of formation of the temperature distribution, that is, by lowering a heating value. The heater elements 43A to 43E having the lowered temperature may have the same temperature between them. Further, they may have different temperatures from one another like the case of formation of the temperature distribution of the wafer W. After the formation of the temperature distribution of the wafer W, the supply of power to the heater elements 43A to 43E may be stopped in order to lower the temperature of the heater elements 43A to 43E, and the interior of the vacuum vessel 11 may be heated only by the heater 42 during execution of the cycle of ALD.

Also, the present disclosure is not limited to the configuration in which the temperature distribution is formed among the heater elements 43A to 43E in order to form the temperature distribution having the concentric circular shape on the wafer W. For example, in FIG. 16, the bottom surface 24 of the concave portion 23 of the rotary table 2 is configured by a mounting portion 51 on which the central portion W1 of the wafer W is mounted, a mounting portion 52 on which the middle portion W2 is mounted, and a mounting portion 53 on which the peripheral portion W3 is mounted, and these mounting portions 51 to 53 are formed of materials having different heat capacity. In a case in which the mounting portions 51 to 53 are formed in this manner, when the temperature distribution having the concentric circular shape is formed on the wafer W, for example, the heater elements 43A to 43E are controlled to have, for example, the same temperature between them as described above, at the time when the rotary table 2 is placed in the descending position and the wafer W is placed on the heater elements 43A to 43E.

Since the emissivity of the mounting portions 51 to 53 is different even though the heater elements 43A to 43E have the same temperature, the mounting portions 51 to 53 are heated at different temperatures. Accordingly, the central portion W1, the middle portion W2, and the peripheral portion W3 of the wafer W are heated at different temperatures, and thus, the temperature distribution having a concentric circular shape is formed on the wafer W on the mounting portions 51 to 53. For example, when a TiO₂ film 20 in which a film thickness of the center side is great is formed as illustrated in FIG. 13, aluminum (Al):0.04 (38 degrees C.)−0.08 (538 degrees C.) is used as a material of the mounting portion 51, stainless steel (SUS):0.44 (216 degrees C.)−0.36 (490 degrees C.) is used as a material of the mounting portion 52, and quartz:0.92 (260 degrees C.)−0.42 (816 degrees C.) is used as a material of the mounting portion 53. Further, regarding the Al, SUS, and quartz described above, a range of emissivity of each of the materials is described after a portion ┌:┘. Also, the temperature of each of the materials when the numerical values of the emissivity described before the parenthesis are determined is described in the parenthesis.

Also, the present disclosure is not limited to the formation of the temperature distribution having a concentric circular shape by heating the wafer W from a lower side of the rotary table 2. For example, a lamp heater may be installed to face the rotary table 2 in the ceiling plate 12 and light is irradiated to a lower side to heat the wafer W to form the temperature distribution. For example, when the temperature distribution is formed by the lamp heater, the rotary table 2 is stopped from rotation in a state where the rotary table 2 is placed in the ascending position, and after the temperature distribution is formed, the rotary table 2 is rotated in the ascending position and an output of the lamp heater is lowered to lower a supply amount of heating energy to the wafer W, and as described above, the cycle of ALD is performed.

Although the formation of the TiO₂ film 20 has been described as an example, the present disclosure is not limited to TiO₂ as a film formed on the wafer W. For example, a silicon oxide (SiO₂) film may be formed by using a silicon (Si)-containing gas such as bis-tertiary-butyl amino silane (BTBAS), instead of the Ti-containing gas, as a raw material gas. In addition, the present disclosure may be applied to a case in which an adsorption amount of a process gas to the substrate can be adjusted depending on an in-plane temperature of the substrate. Thus, the present disclosure is not limited to the application to the film forming apparatus for performing film formation through ALD and may also be applied to an apparatus for performing film formation through CVD.

In the foregoing example, the three regions in the plane of the wafer W are heated at different temperatures, but the temperature distribution may also be formed by heating more regions at different temperatures. For example, all of the heater elements 43A to 43E may be controlled to have different temperatures and respective portions of the wafer W respectively corresponding to the heater elements 43A to 43E may be heated to have different temperatures. Also, only two heater elements, one of which is a heater element for heating the central portion of the wafer W and the other of which is a heater element for heating the peripheral portion of the wafer W, may be installed and the temperature distribution having a concentric circular shape may be formed on the wafer W.

However, the present disclosure may also be applied to a case in which a substrate having an angular shape is processed. In this case, for example, the heater elements 43B to 43E of the heater 43 may have an angular ring shape along the periphery of the angular substrate, instead of a circular ring shape. That is, in the present disclosure, an in-plane temperature distribution having a concentric shape is formed on the substrate, thereby forming a film thickness distribution having the concentric shape. The in-plane temperature distribution having a concentric shape is not limited to a geometrically concentric shape and may include a case in which a region of a substantially same temperature is formed in a circumferential direction of the substrate and the regions are plurally present when viewed in a diameter direction of the substrate.

Moreover, the configuration examples of the apparatus described above may be combined. Specifically, for example, as described above, after the mounting portions 51 to 53 having different materials are formed, a temperature distribution may be formed among the heater elements 43A to 43E and a temperature distribution having a concentric circular shape may be formed on the wafer W. Further, in order to reduce a heating energy of the heater 43 supplied to the wafer W, an output of the heater 43 may be lowered while the rotary table 2 may be moved to the ascending position.

### (Evaluation Tests)

### Evaluation Test 1

In evaluation test 1-1, a TiO₂ film was formed on a wafer W through a film forming process in substantially the same manner as that of the film forming process of the film-forming processing apparatus 1 described above. The film forming process of evaluation test 1-1 is different from the foregoing film forming process, in that a temperature distribution having a concentric circular shape is not formed on the wafer W when the cycle of ALD described above is performed. Also, in the film forming process of evaluation test 1-1, whenever the process is performed, the temperature of the wafer W when the cycle is performed was changed within a range of 150 to 180 degrees C. Regarding the wafer W after the film forming process, a film thickness of the TiO₂ film was measured and a deposition rate (unit: nm/min.) obtained by dividing the measured film thickness by a time during which film formation was performed was calculated.

Further, in evaluation test 1-2, the same test as that of evaluation test 1-1 was performed, except for formation of an SiO₂ film, instead of the TiO₂ film, and a change in the temperature of the wafer W within a range of 50 to 70 degrees C. in every film forming process. Also, in evaluation test 1-3, the same test as that of evaluation test 1-1 was performed, except for formation of an SiO₂ film, instead of the TiO₂ film, and a change in the temperature of the wafer W within a range of 590 to 637 degrees C. in every film forming process.

In evaluation test 1-1, the deposition rate calculated from each wafer W was a value within a range of 5.905 nm/min. to 5.406 nm/min, and the deposition rate was reduced as the temperature was increased. In some of the obtained deposition rates, when the temperatures of the wafers W were 150 degrees C., 160 degrees C., 170 degrees C., and 180 degrees C., the deposition rates were 5.905 nm/min, 5.726 nm/min, 5.560 nm/min, and 5.406 nm/min.

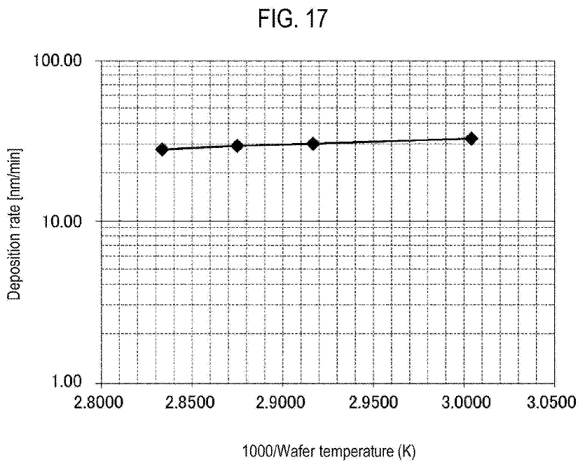

In evaluation test 1-2, the deposition rate calculated from each wafer W was a value within a range of 33.401 nm/min to 29.534 nm/min. The single logarithm graph of FIG. 17 is a graph obtained from the result of evaluation test 1-2, and the vertical axis is a deposition rate and the horizontal axis is 1000/(temperature (unit: K) of wafer W). When the value of the vertical axis is Y and the value of the horizontal axis is X, an approximate expression obtained from the measurement result is Y=4.741e^{0.6817X}, and the deposition rate tends to be reduced as the temperature is increased.

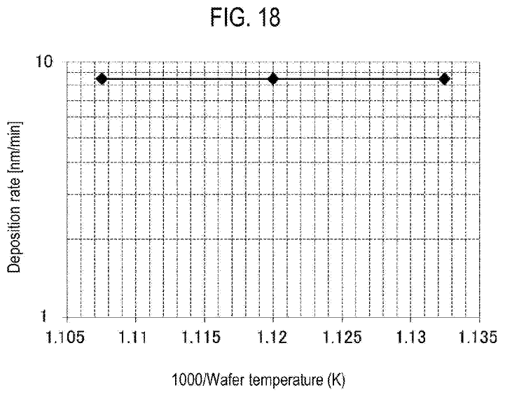

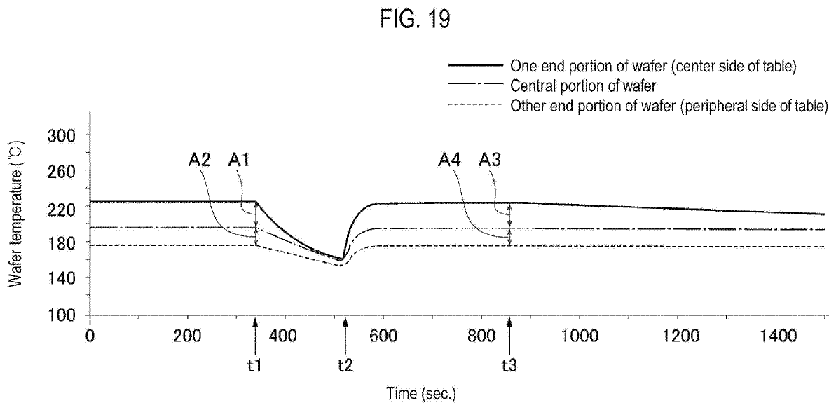

In evaluation test 1-3, the deposition rate calculated from each wafer W was a value within a range of 8.187 nm/min. to 8.657 nm/min. The single logarithm graph of FIG. 18 shows the result of evaluation test 1-3 in the same manner as that of FIG. 17. The value of the vertical axis of the graph is Y and the value of the horizontal axis of the graph is X, an approximate expression obtained from the measurement result is Y=24.202e^{-0.932X}, and a coefficient R² of determination of the approximate expression is 0.9209. As illustrated in the graph, in evaluation test 1-3, the deposition rate tends to be increased as the temperature is increased. Thus, the deposition rate appears to be dependent upon a temperature of the wafer W from the results of evaluation tests 1-1 to 1-3. Thus, as described above with reference to FIGS. 6 to 13, it is estimated that a film thickness of each portion in the plane of the wafer W can be controlled by controlling the in-plane temperature distribution of the wafer W.

### Evaluation Test 2

In evaluation tests 2-1 to 2-3, the wafer W is mounted on the rotary table 2 of a film-forming processing apparatus configured to be substantially the same as the film-forming processing apparatus 1 illustrated in FIG. 1 and heated by the heater, a distance between the heater and the wafer W is changed by the lift pins 27, and thereafter, the supply of power to the heater was stopped. In this manner, the operations of the lift pins 27 and the heater were controlled and the transition of a temperature of each portion of the wafer W was inspected by using a thermocouple installed in each portion of the wafer W. In the film-forming processing apparatus of evaluation test 2, the heater 43 was not installed and the heater 42 was formed to have a concentric circular shape in a circumferential direction of the rotary table 2 to heat the wafer W.

In evaluation tests 2-1, 2-2, and 2-3, an output of the heater 42 was set such that the temperatures of the central portions of the wafers W when the wafers W were mounted on the rotary table 2 during the operation of the heater 42 were 200 degrees C., 400 degrees C., and 550 degrees C., respectively. Further, the temperature measurement of the wafer W was performed on three portions of the central portion of the wafer W, an end portion (referred to as one end portion) of the center side of the rotary table 2 in the wafer W, and an end portion (referred to as the other end portion) of the peripheral side of the rotary table 2 in the wafer W, and, the rotary table 2 was stopped while the temperatures were measured. An output of the heater 42 was controlled such that the temperature of one end portion of the wafer W is higher than that of the central portion of the wafer W, the temperature of the other end portion of the wafer W is lower than that of the central portion of the wafer W when the wafer W is mounted on the rotary table 2 during the operation of the heater 42.

The differences of the film-forming processing apparatus used in evaluation test 2 from the film-forming processing apparatus 1, other than the configuration of the heater are that an SiH₂Cl₂ gas was supplied as a raw material gas, instead of the Ti-containing gas, from the gas nozzle 31, that two gas nozzles 33 are installed to be spaced apart in a circumferential direction of the rotary table 2, that an N₂ gas for nitriding the raw material gas is supplied, instead of an O₃ gas, from each gas nozzle 33, and that a plasma forming part for forming plasma is installed in a region to which the N₂ gas is supplied by each gas nozzle 33. However, the plasma was not formed while the temperature of the wafer was measured. Further, the two gas nozzles 33 were installed from one separation region D to the other separation region D along the circumferential direction of the rotary table 2.

During the measurement of the temperature, an internal pressure of the vacuum vessel 11 was set to 1.8 Torr (240 Pa), and a refrigerant was supplied to a flow channel (not shown) installed in the wall portion of the vacuum vessel 11 to cool the wall portion to 85 degrees C. Regarding a flow rate of a gas supplied to each part of the film-forming processing apparatus during the measurement of the temperature, an N₂ gas of 5000 sccm was supplied to each gas nozzle 33, an N₂ gas of 1000 sccm was supplied to the region C of the central portion, and an N2 gas of 1000 sccm was supplied to the gas nozzles 32 and 34. Also, an SiH₂Cl₂ gas generated by supplying an N₂ gas of 1000 sccm to a tank in which solid SiH₂Cl₂ is stored to vaporize SiH₂Cl₂, and the N₂ gas used to vaporize SiH₂Cl₂ were supplied to the gas nozzle 31.

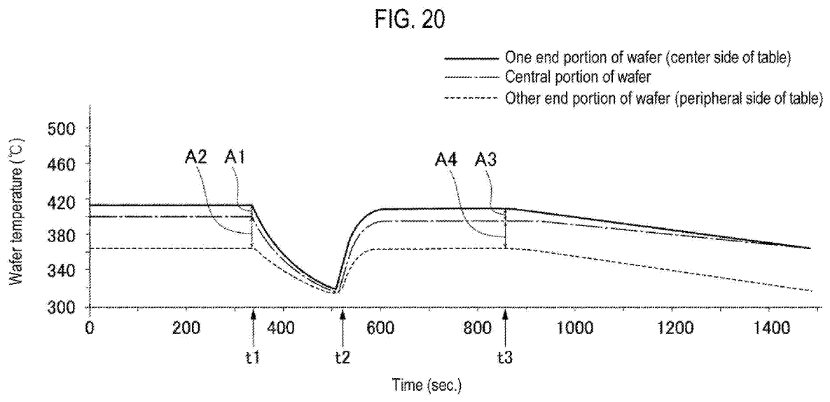

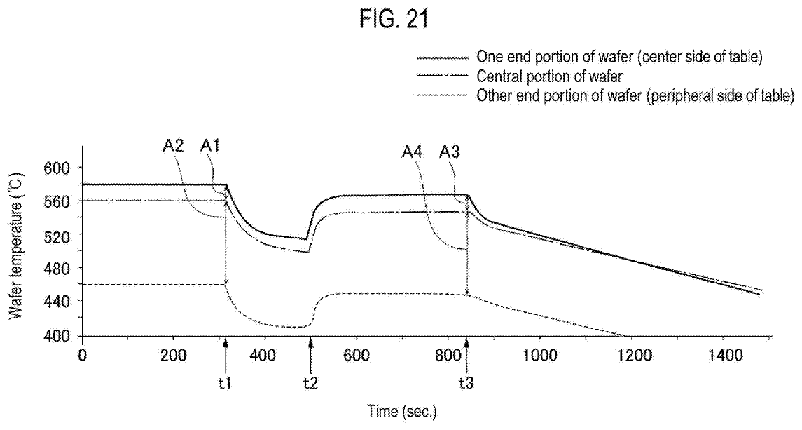

FIGS. 19, 20, and 21 are graphs illustrating the results of evaluation tests 2-1, 2-2, and 2-3. In each graph, the vertical axis indicates the measured temperature (unit: degrees C.) of the wafer W, and the horizontal axis indicates an elapse time (unit: sec.) after the measurement of the temperature was started. In the graphs, the temperatures of one end portion, the central portion, and the other end portion of the wafer W are indicated by the alternate long and short dash line, the solid line, and the dotted line. In the graphs, a time t1 is a time at which the lift pins 27 ascended. As the lift pins 27 ascended, the wafer W ascended from the rotary table 2, increasing a distance between the wafer W and the heater 42. A time t2 after the time t1 is a time at which the lift pin 27 descended. As the lift pins 27 descended, the wafer W was mounted again on the rotary table 2. A time t3 after the time t2 is a time at which the supply of power to the heater 42 was stopped.

In evaluation tests 2-1 to 2-3, from the time t1 to the time t2 and after the time t3, as illustrated in the graphs, a temperature difference among the central portion, one end portion, and the other end portion of the wafer W is gradually reduced, and the temperatures of the central portion, the one end portion, and the other end portion were gradually lowered. In evaluation test 2-1, a temperature difference (referred to as A1) between the one end portion and the central portion of the wafer W at the time t1 was 26.3 degrees C., and a temperature difference (referred to as A2) between the other end portion and the central portion of the wafer W was 20.2 degrees C. Further, regarding the central portion and the one end portion of the wafer W, an elapse time (referred to as B1) from the time t1 at which 2 degrees C. was reduced compared with a temperature difference at the time t1 was 5 seconds. Also, regarding the peripheral portion and the central portion of the wafer W, an elapse time (referred to as B2) from the time t1 at which 2 degrees C. was reduced compared with a temperature difference at the time t1 was 9 seconds.

Further, in evaluation test 2-1, a temperature difference (referred to as A3) between the one end portion and the central portion of the wafer W at the time t3 was 27.3 degrees C., and a temperature difference (referred to as A4) between the other end portion and the central portion of the wafer W was 19.7 degrees C. Also, regarding the central portion and the one end portion of the wafer W, an elapse time (referred to as B3) from the time t3 at which 2 degrees C. was reduced compared with a temperature difference at the time t3 was 1103 seconds. Also, regarding the peripheral portion and the central portion of the wafer W, an elapse time (referred to as B4) from the time t3 at which 2 degrees C. was reduced compared with a temperature difference at the time t3 was 1409 seconds. In evaluation test 2-2, the temperature differences A1, A2, A3, and A4 were 10.5 degrees C., 36.0 degrees C., 12.7 degrees C., and 32.8 degrees C., respectively, and the elapse times B1, B2, B3, and B4 were 3 seconds, 6 seconds, 44 seconds, and 160 seconds, respectively. In evaluation test 2-3, the temperature differences A1, A2, A3, and A4 were 17.1 degrees C., 102.1 degrees C., 18.8 degrees C., and 98.3 degrees C., respectively, and the elapse times B1, B2, B3, and B4 were 4 seconds, 18 seconds, 3 seconds, and 8 seconds, respectively.

Further, an elapse time until the temperature of one end portion of the wafer W was dropped by 2 degrees C. from the time t1 is C1, a temperature difference between one end portion and the central portion of the wafer W when 2 degrees C. was dropped in this manner is D1, and a temperature difference between the other end portion and the central portion of the wafer W is D2. Also, an elapse time until the temperature of one end portion of the wafer W was dropped by 2 degrees C. from the time t3 is C2, a temperature difference between one end portion and the central portion of the wafer W when 2 degrees C. was dropped in this manner is D3, and a temperature difference between the other end portion and the central portion of the wafer W is D4. In evaluation test 2-1, C1, C2, D1, D2, D3, and D4 were 5 seconds, 168 seconds, 24.7 degrees C., 18.2 degrees C., 27.3 degrees C., and 19.9 degrees C., respectively. In evaluation test 2-2, C1, C2, D1, D2, D3, and D4 were 3 seconds, 130 seconds, 8.5 degrees C., 34.1 degrees C., 9.1 degrees C., and 34.0 degrees C., respectively. In evaluation test 2-3, C1, C2, D1, D2, D3, and D4 were 4 seconds, 3 seconds, 15.1 degrees C., 100.4 degrees C., 16.8 degrees C., and 98 degrees C., respectively.

After the times t1 and t3, the temperatures of each portion of the wafer W and a temperature difference between the portions of the wafer W are maintained for a moment. In particular, in evaluation tests 2-1 and 2-2, after the time t3, it can be seen that the temperatures of each portion of the wafer W are difficult to lower for a relatively long period of time and that a temperature difference between the portions of the wafer W is maintained for a relatively long period of time. This is because, the temperature of the wafer W when it is heated by the heater is relatively low, and thus, it is difficult to be affected by the sidewall of the vacuum vessel 11 which has been cooled as described above. From the results of evaluation test 2, as described in the embodiment of the present disclosure, it can be seen that it is possible to form the temperature distribution on the wafer W and that the film formation can be performed in a state where the temperature distribution is maintained.

According to the present disclosure in some embodiments, in performing a film forming process by supplying a process gas to a substrate while revolving the substrate by rotating a rotary table, the substrate is heated by a heating part such that an in-plane temperature distribution having a concentric circular shape is formed on the substrate before the film forming process, and thereafter, in a state where a heating energy received by the substrate from the heating part is reduced, the film forming process is performed by rotating the substrate. Thus, it is possible to form an in-plane film thickness distribution having a concentric circular shape on the substrate using an apparatus that performs the film forming process while revolving the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1-5. (canceled)

6. A method of forming a film by supplying a process gas to a substrate which is mounted on one surface side of a rotary table installed in a vacuum vessel, the substrate being revolved by a rotation of the rotary table, comprising:
using a first heating part and a second heating part, the second heating part being installed to face the rotary table, corresponding to the substrate mounted on the rotary table;
heating an entire heat treatment region of the substrate in the vacuum vessel by the first heating part;
setting a rotation position of the rotary table such that the substrate on the rotary table is placed in a position corresponding to the second heating part and forming an in-plane temperature distribution having a concentric shape on the substrate by heating the substrate by the second heating part; and
performing a film forming process by supplying a process gas to the substrate by rotating the rotary table in a state where a heating energy received by the substrate from the second heating part is smaller than that in the setting the rotation position of the rotary table.

7. (canceled)

8. The method of claim 6, wherein a distance between the rotary table and the second heating part is greater in the performing the film forming process than that in the setting the rotation position of the rotary table.

9. The method of claim 6, wherein a heating value of the second heating part is smaller in the performing the film forming process than that in the setting the rotation position of the rotary table.

10. The method of claim 6, wherein the setting the rotation position of the rotary table and the performing the film forming process are repeatedly performed.

11. The method of claim 6, further comprising:
heating the entire substrate on the rotary table by the second heating part at a temperature equal to or higher than the highest temperature in the in-plane of the substrate that is available when the in-plane temperature distribution having the concentric shape is formed in the setting the rotation position of the rotary table, before the substrate subjected to the film forming process is unloaded from the vacuum vessel.

12. A non-transitory computer-readable recording medium storing a program for use in a film-forming processing apparatus for performing a film formation by supplying a process gas to a substrate which is mounted on one surface side of a rotary table installed in a vacuum vessel, the substrate being revolved by a rotation of the rotary table,
wherein the program has groups of steps organized to execute the method of forming a claim 6.
